(19) United States
(12) Patent Application Publication
(10) Pub. No.: US 2025/0085234 A1
(43) Pub. Date: Mar. 13, 2025

(54) USE OF LAYOUT ANALYSIS TO ENABLE EFFICIENT AND EFFECTIVE RANDOM DEFECT INSPECTION USING A VECTOR-MODE E-BEAM INSPECTION MACHINE

(71) Applicant: PDF Solutions, Inc., Santa Clara, CA (US)

(72) Inventors: Hans Eisenmann, Munich (DE); Markus Rauscher, Munich (DE); Christian Sendner, Munich (DE)

(21) Appl. No.: 18/829,227

(22) Filed: Sep. 9, 2024

Related U.S. Application Data
(60) Provisional application No. 63/537,420, filed on Sep. 8, 2023.

(51) Int. Cl. G01N 21/95

(52) U.S. Cl. CPC G01N 21/9505

(57) ABSTRACT

A vector e-beam machine for random defect inspection is disclosed. Contrary to traditional wisdom, it is shown that through a careful choice of target locations, vector machines can provide high-throughput and high coverage even when scanning for random defects. Additionally, by not wastefully scanning locations that provide no additional fault observability, charge accumulation on the wafer—a major concern in e-beam scanning—is reduced.

In a preferred embodiment, two approaches are combined:
1) Scan/target only at locations where a random failure can be observed.
2) From the defined list of observable locations, scan/target only the points which have the highest efficiency.

Use of these and/or other disclosed techniques enables the scanner to target and evaluate a majority of the total observable defects in a single pass.

### CROSS-REFERENCE TO RELATED APPLICATION

This application claims priority to U.S. Prov. Pat. Applic. Ser. 63/537,420, filed Sep. 8, 2023, by the inventors herein, which '420 application is incorporated by reference herein.

### FIELD OF THE INVENTION

The present invention relates generally to the field of wafer inspection, more particularly to the field of random defect inspection, and also more particularly to e-beam inspection in voltage contrast mode.

### BACKGROUND

Currently, there are two ways to do inspection on a wafer. Optical inspection is fast but has limitations for today's small features (specifically for opens). Electron beam inspection can resolve small features but is prohibitively slow (the need for a fast electron beam inspection can be seen by industry's push toward multibeam machines).

Presently, electron-beam inspection for random defects uses raster machines. This is because contrary to systematic defects, random defects can occur at every location and, therefore, traditional thinking is to use a machine that takes full-area images.

### SUMMARY OF THE INVENTION

This invention proposes to use a vector e-beam machine instead of a raster machine for random defect inspection. Contrary to traditional wisdom, the inventors herein show that through a careful choice of target locations, vector machines can provide high-throughput and high coverage even when scanning for random defects. Additionally, by not wastefully scanning locations that provide no additional fault observability, charge accumulation on the wafer—a major concern in e-beam scanning—is reduced.

The focus here is not on sparsely occurring specific systematics locations (which would be the typical application of a vector e-beam machine), but on inspect as much as possible of the potential random defects efficiently.

In a preferred embodiment, two approaches are combined:
1) Scan/target only at locations where a random failure can be observed.
2) From the defined list of observable locations, scan/target only the points which have the highest efficiency. For example, some scan points might observe 0.3 micron of line opens, whereas other scan points observe several microns of line opens. Throughput can be increased by omitting the scan points with low efficiency. The preferred approach is the assign a budgeted number of scan points per area (typically in alignment with stage speed and scan time/point). Then, sort by efficiency and use the most efficient points within the budget.

Now, generally speaking, and without intending to be limiting, one aspect of the invention relates to methods of testing processed semiconductor wafers, using voltage contrast inspection (VCI), to detect manufacturing defects therein, said processes comprising, for example, at least the following steps: (a) performing a computer-assisted layout analysis of the wafer's design to identify features on the wafer where a short or open defect would be observable by VCI; (b) based on available scanning capacity of a VCI scanner, selecting features corresponding to a subset of the observable short and/or open defects identified in step (a) for targeting by the VCI scanner; (c) scanning only the selected features to determine the presence or absence of the observable defects selected in step (b); and (d) whereby a the VCI scanner targets and evaluates a majority of the total VCI-observable defects in a single pass.

In some embodiments, the layout analysis of step (a) only considers open defects.

In some embodiments, the layout analysis ignores redundant segments.

In some embodiments, the layout analysis ignores features where a distance from a line end to a via is too short to permit defect detection by VCI.

In some embodiments, the layout analysis ignores features that are not grounded.

And in some embodiments, the layout analysis of step (a) only considers short defects.

In some embodiments, the layout analysis ignores hard grounded features.

In some embodiments, the layout analysis ignores features that would be unobservable because of an absence of any brighter neighbor.

Some embodiments further involve the step of: (a2) performing a second computer-assisted layout analysis of the wafer's design to identify features on the wafer where a short or open defect would be observable by VCI under reverse biased conditions.

In some embodiments, the layout analyses of steps (a) and (a2) are compared and used to determine whether to scan using normal or reverse bias conditions.

And in some embodiments, the layout analyses of steps (a) and (a2) are analyzed to determine which defects to scan using normal bias conditions and which defects to scan using reverse bias conditions.

### BRIEF DESCRIPTION OF THE DRAWINGS

These, as well as other, features, aspects, and advantages of the present invention are illustrated in the accompanying set of drawings, which is intended be considered along with the accompanying text, and in which:

FIG. 1A depicts an overall, simplified flow of an illustrative embodiment;

FIG. 1B depicts the speedup and efficiency gain that the invention enables on an exemplary commercial layout;

FIG. 2A conceptually illustrates the layout analysis process for evaluating observability of open faults and FIG. 2B shows the scan point reductions that result from this process;

FIG. 3A conceptually illustrates the layout analysis process for evaluating observability of short faults and FIG. 3B shows the scan point reductions that result from this process;

FIG. 4 illustratively depicts the number of observable features in relation to the capability (e.g., stage speed) of the exemplary e-beam scanner;

FIG. 5 illustratively depicts how to choose features for targeting in the case of a dense block where the number of observable faults exceeds the capacity of the scanner;

FIGS. 6A-B and 7A-B depict the risk coverage breakdowns for open and short faults, respectively, and FIG. 8 summarizes this data in tabular form;

FIGS. 9 and 10A-B depict available grounding via processing options;

FIGS. 11A-D depict examples of testable line segments for exemplary M0, M1, M2, and M3 patterns; and

FIGS. 12A-B depict alternative exemplary flows for an embodiment in which the observability of short and open faults is evaluated under both normal and reverse bias (i.e., switch ground and VDD) conditions.

### DESCRIPTION OF EXEMPLARY EMBODIMENT(S)

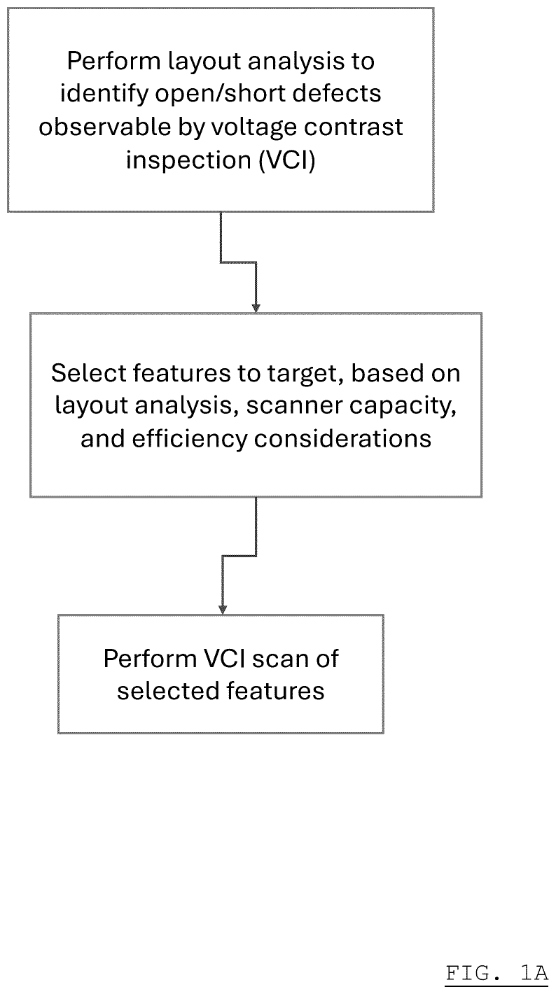

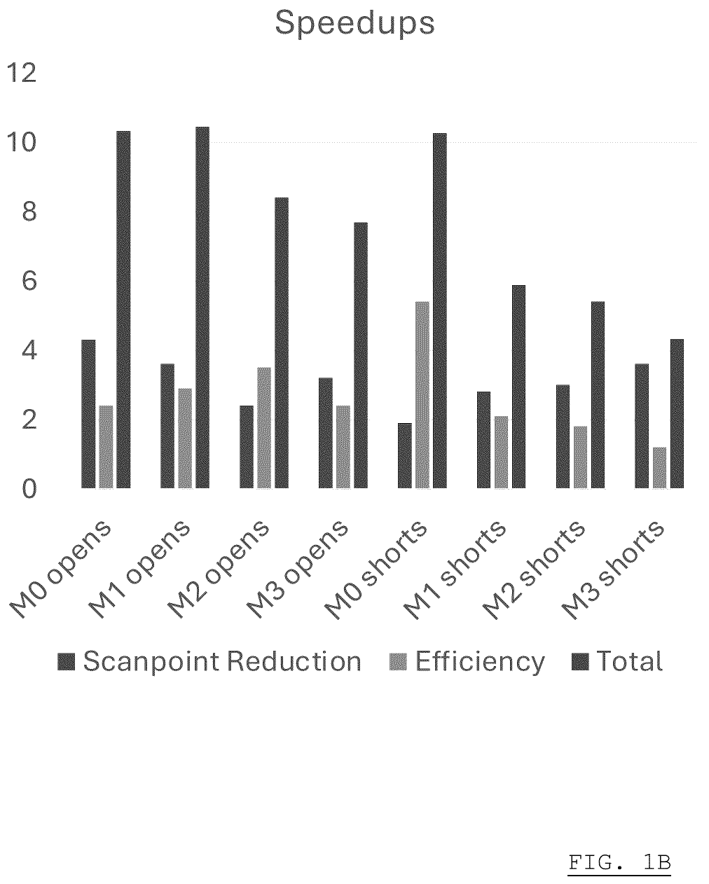

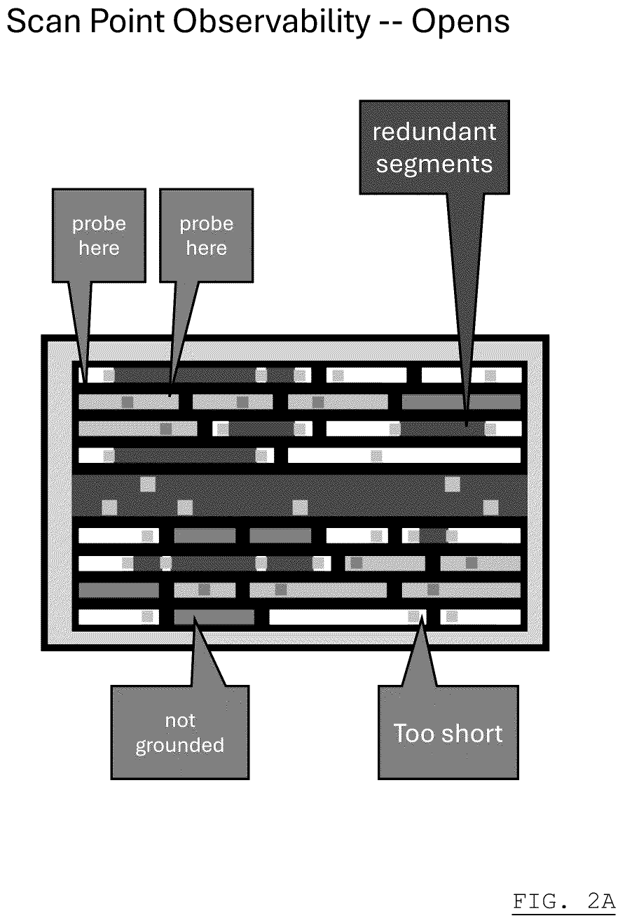

Referring first to FIG. 1A, which depicts an overall, simplified flow of an illustrative embodiment, this embodiment comprises three basic steps:
(i) Perform layout analysis to identify open/short defects observable by voltage contrast inspection (VCI);
(ii) Select features to target, based on layout analysis, scanner capacity, and efficiency considerations; and
(iii) Perform a VCI scan of selected features.

Referring now to FIG. 1B, which depicts the speedup and efficiency gain that the invention enables on an exemplary commercial layout, the depicted speedup corresponds to the product of measurement efficiency gain (i.e., only pick the points with the highest defect risk) and scan point reduction (i.e., ignore points which do not provide a meaningful VC signal). As depicted, the invention enables speedups of about 4× to 10× on a representative commercial layout.

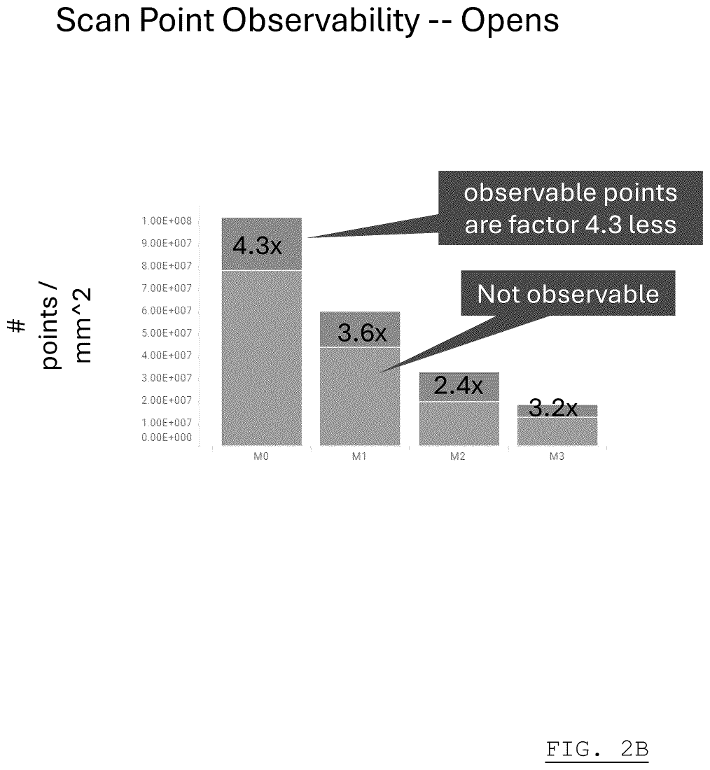

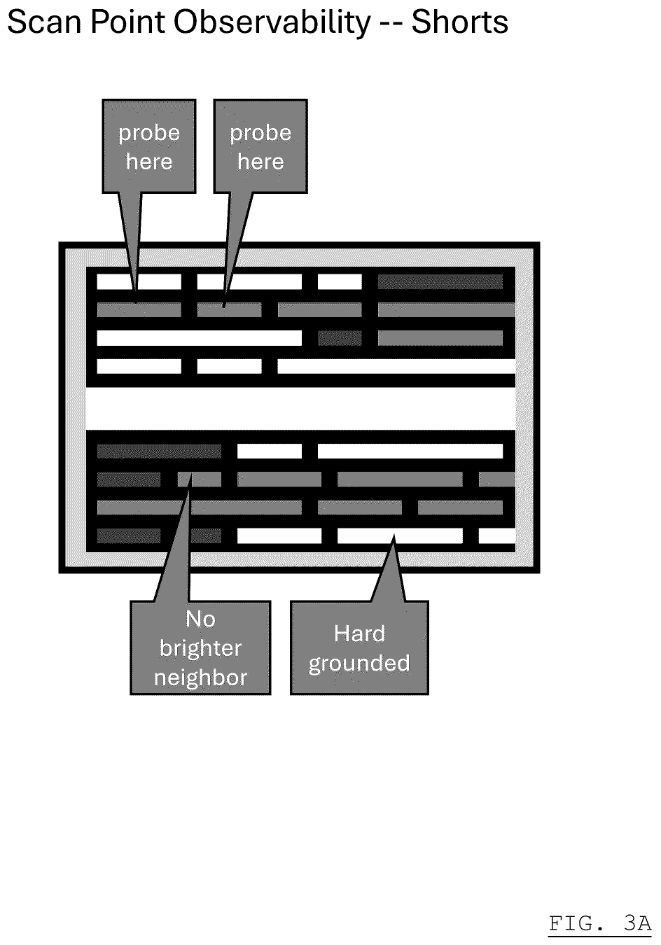

Referring now to FIG. 2A, which conceptually illustrates the layout analysis process for evaluating observability of open faults, the skilled artisan will appreciate that it involves eliminating/ignoring features that are either too short, not grounded, or redundant. This process results in scan point reductions of between 2.4× and 4.3× for the exemplary layout, as depicted in FIG. 2B.

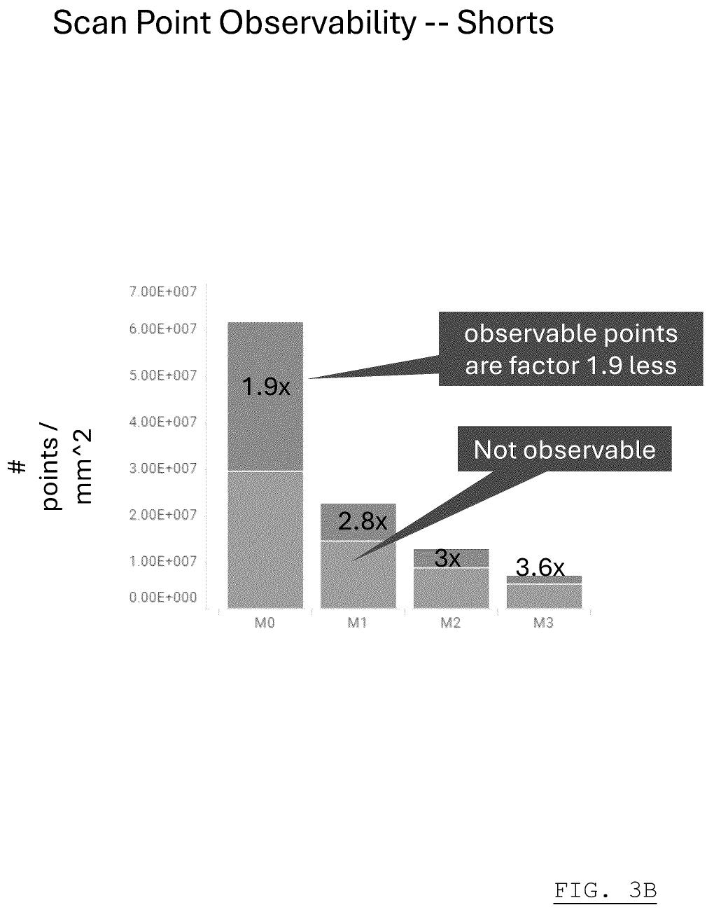

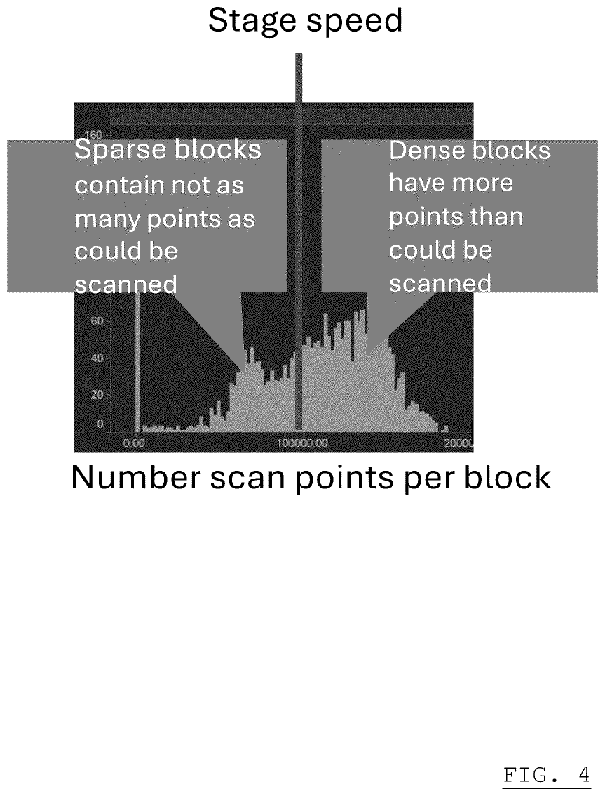

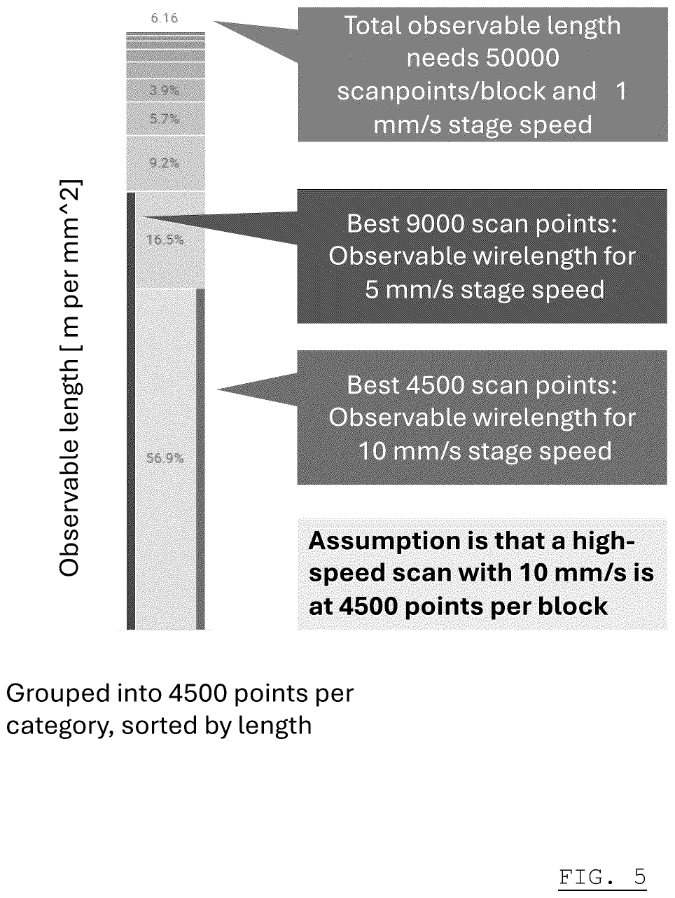

Referring now to FIG. 3A, which conceptually illustrates the layout analysis process for evaluating observability of short faults, the skilled artisan will appreciate that it involves eliminating/ignoring features that are either already hard grounded or not adjacent to any brighter neighbor. This process results in scan point reductions of between 1.9× and 3.6× for the exemplary layout, as depicted in FIG. 3B.

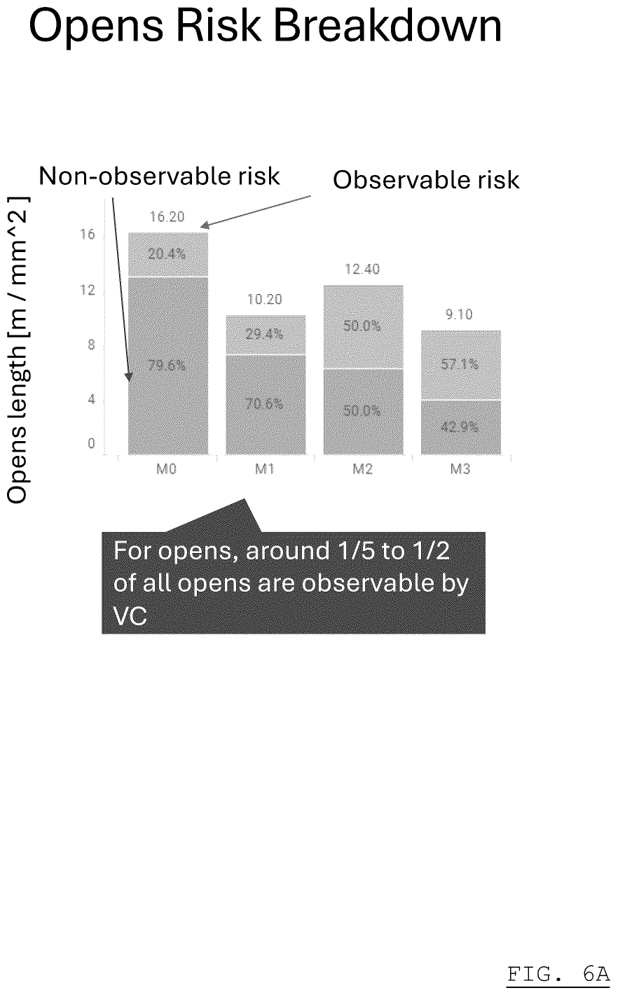

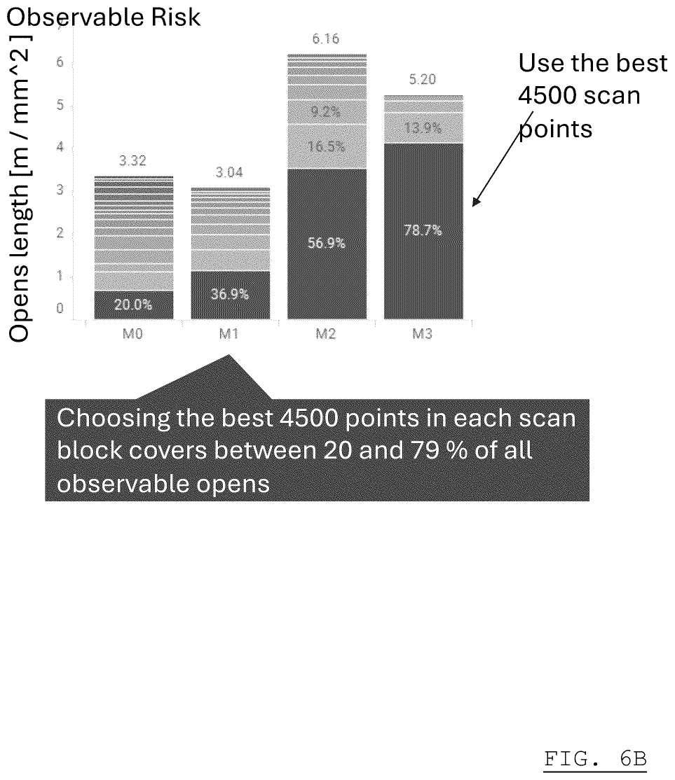

Referring now to FIG. 4, which illustratively depicts the number of observable features in relation to the capability (e.g., stage speed) of the exemplary e-beam scanner, the skilled artisan will appreciate that sparse blocks may not contain as many observable features as could be scanned, whereas dense blocks will typically contain more than can be scanned in a single pass.

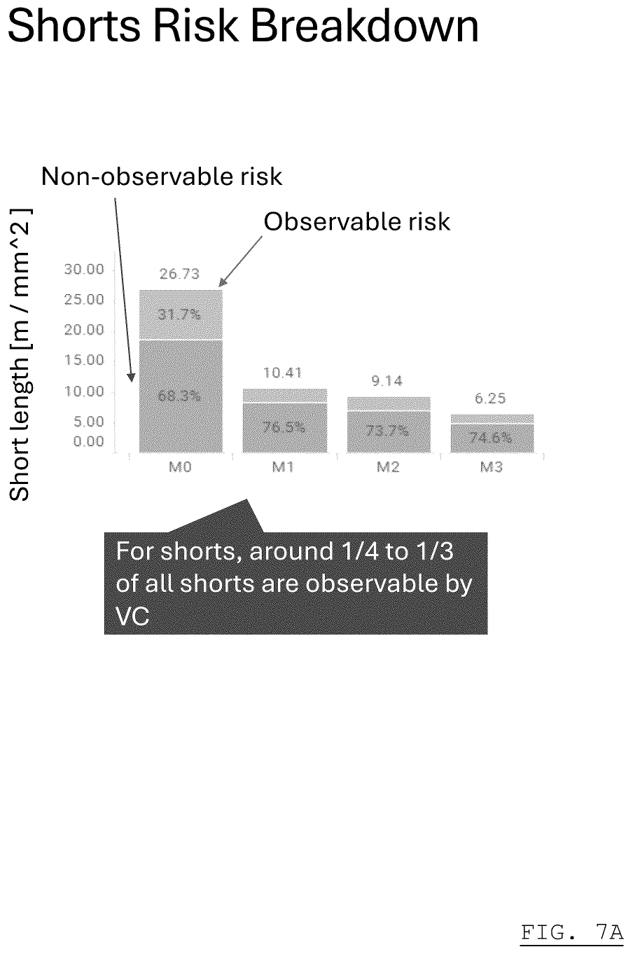

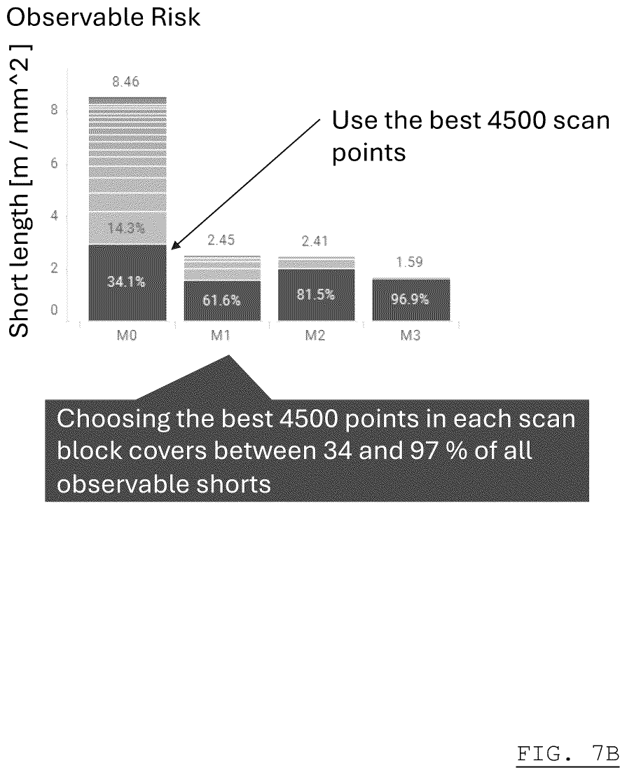

Referring now to FIG. 5, which illustratively depicts how to choose features for targeting in the case of a dense block where the number of observable faults exceeds the capacity of the scanner. In the depicted example,
(i) We assumed a dwell time, block size and stage speed (10 mm/s) which results in 4500 points per scan block;
(ii) We then put the top 4500 points with the highest associated risk (i.e., length) into the first category, the next 4500 points into the next category, etc.
   In this example:
A stage speed of 10 mm/s would scan 57% of all points;
a stage speed of 5 mm/s would scan 57%+16%=73% of all points (i.e., picking the best 4500 scan points makes it 10× faster while still scanning the majority of risk).

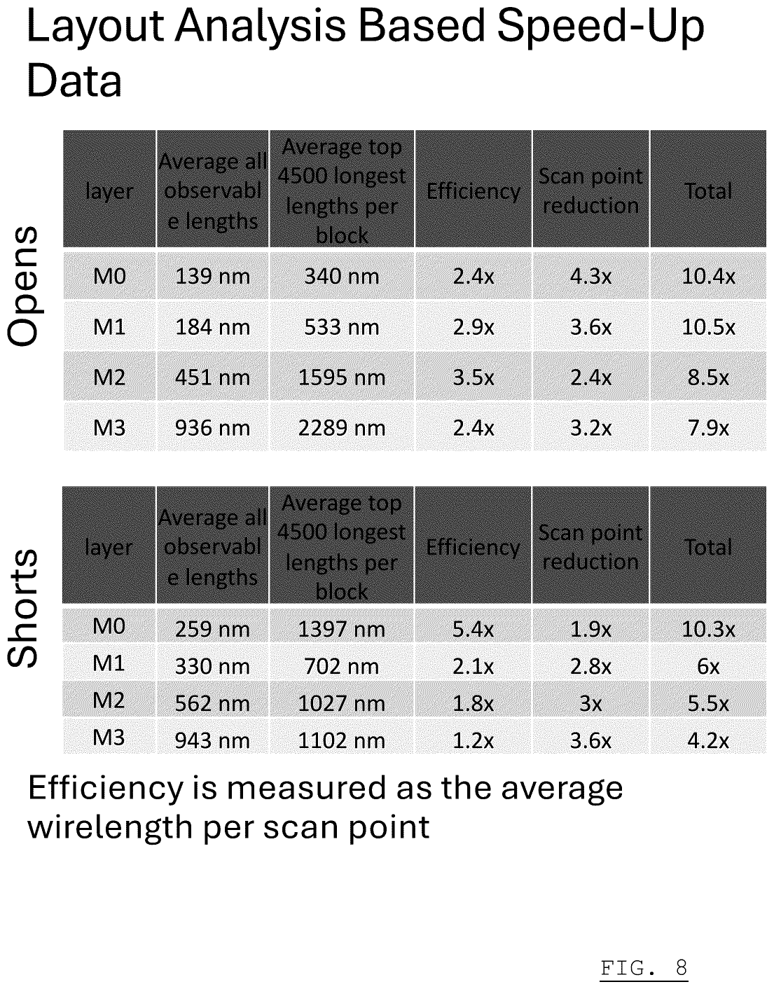

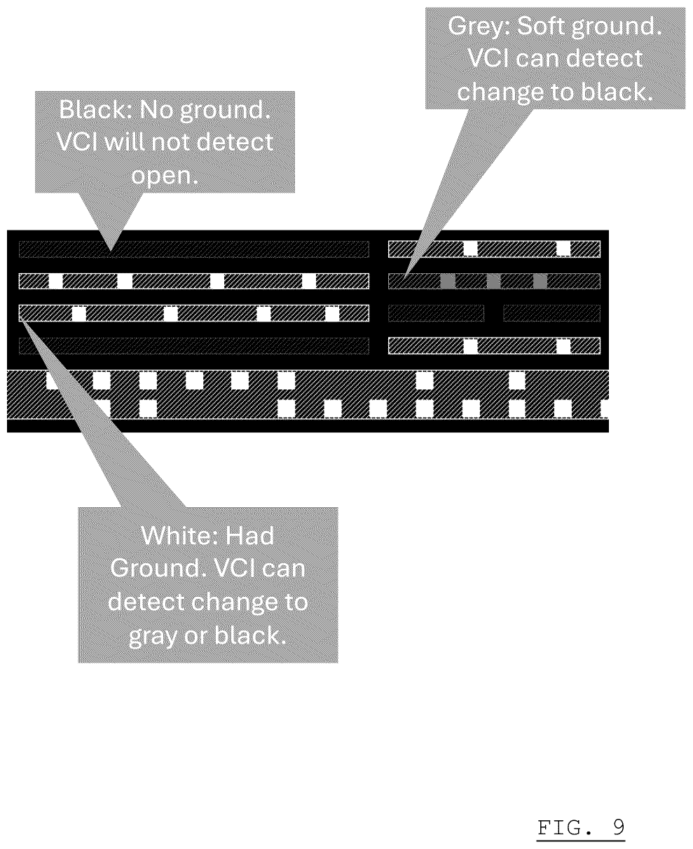

Referring now to FIGS. 6A-B and 7A-B, which depict the risk coverage breakdowns for open and short faults, respectively, and to FIG. 8, which summarizes this data in tabular form, the skilled artisan will appreciate that:
For opens, around ⅕ to ½ of all opens are observable by VC (FIG. 6A);
Choosing the best 4500 points in each scan block covers between 20 and 79% of all observable opens (FIG. 6B);
For shorts, around ¼ to ⅓ of all shorts are observable by VC (FIG. 7A); and
Choosing the best 4500 points in each scan block covers between 34 and 97% of all observable shorts (FIG. 7B).

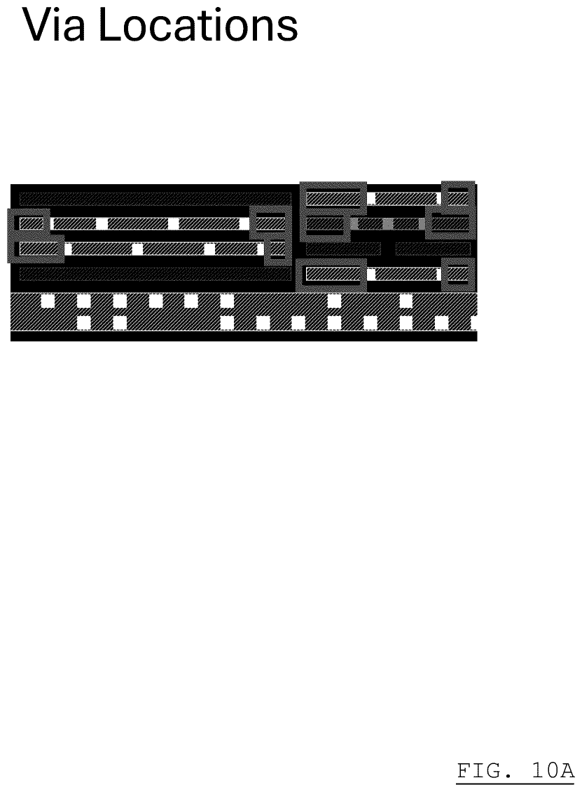

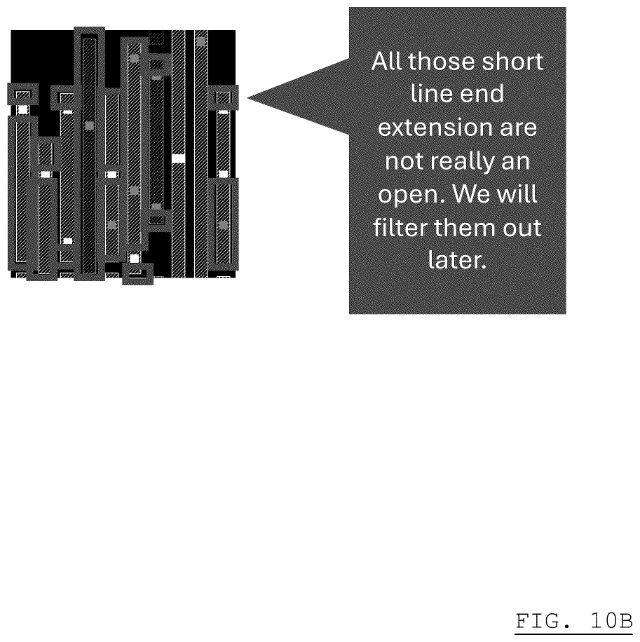

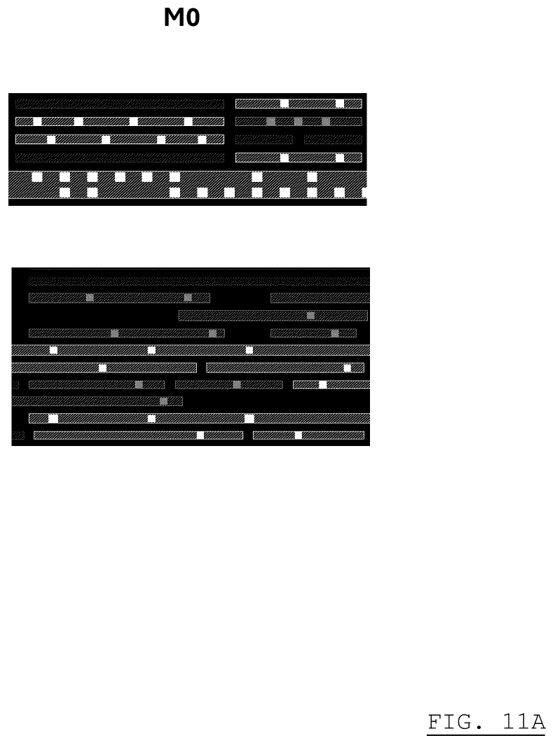

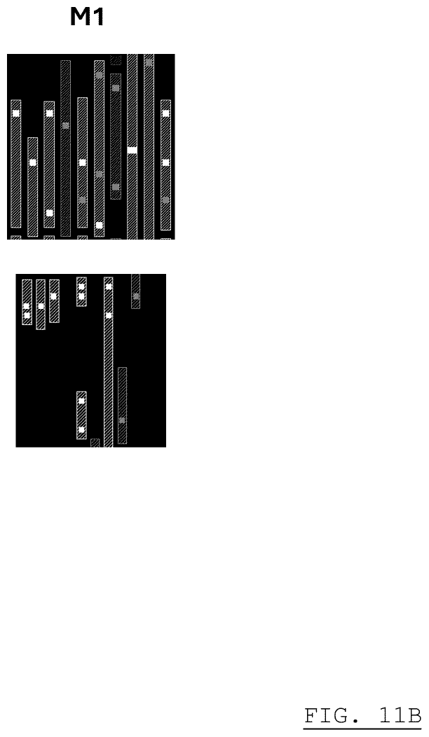

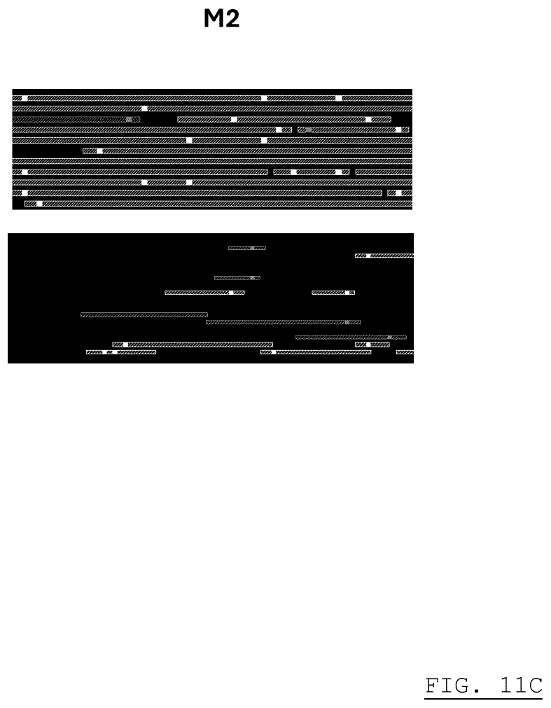

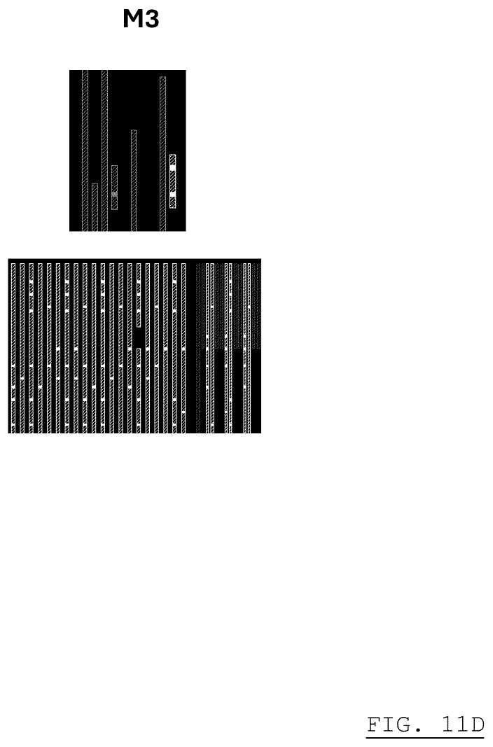

FIGS. 9, 10A-B, and 11A-D will be appreciated by the skilled artisan without additional detailed explanation.

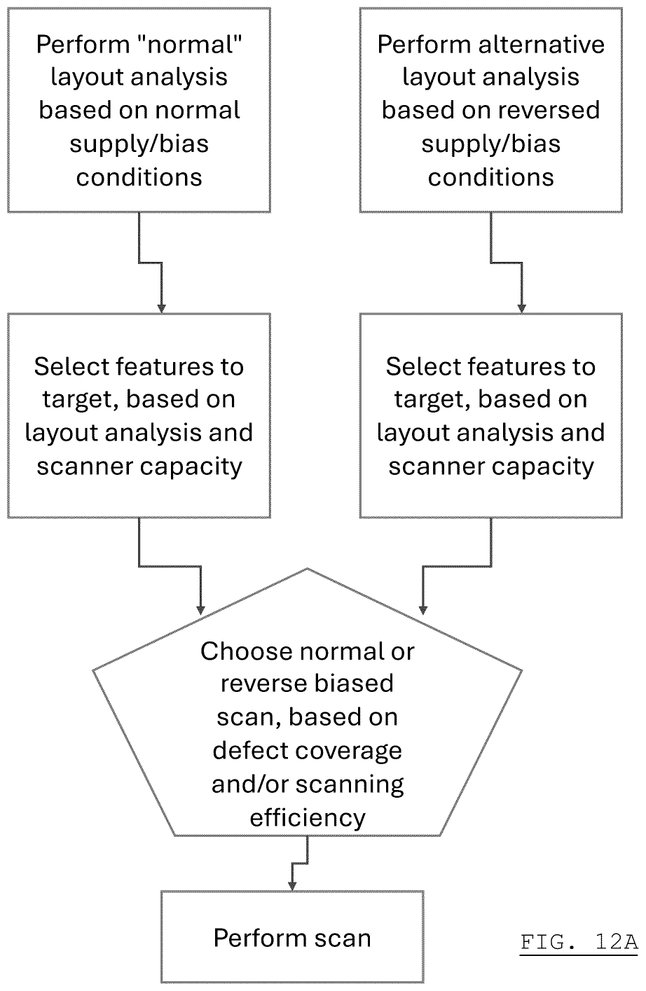

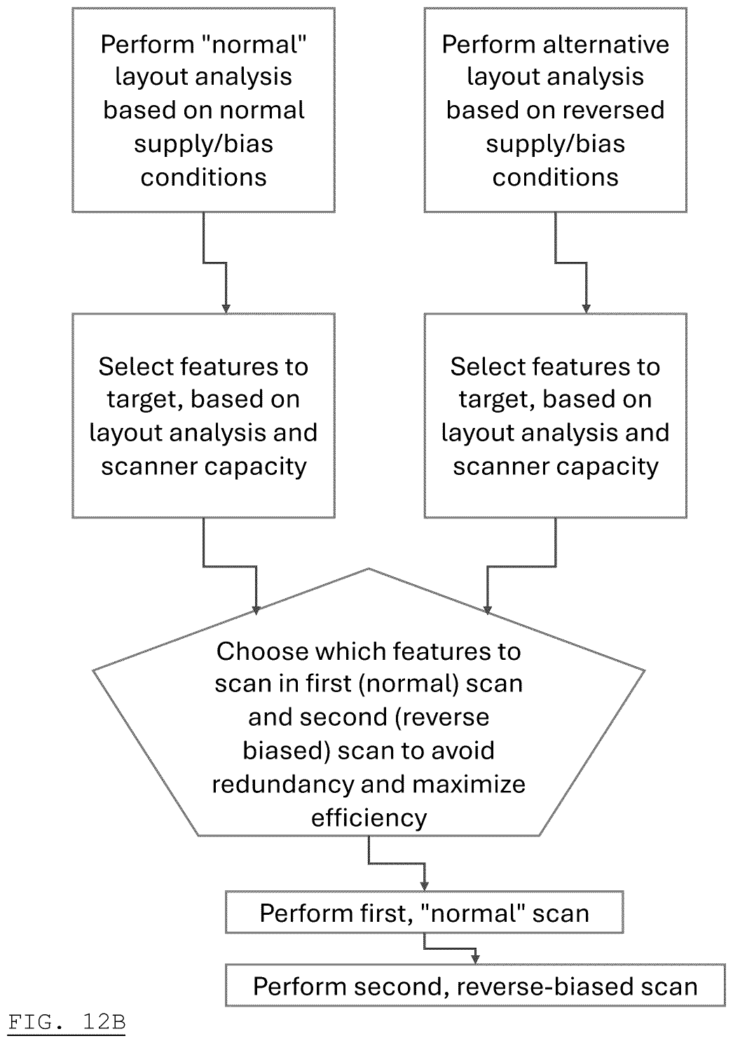

Referring now to FIGS. 12A-B, which depict alternative exemplary flows for an embodiment in which the observability of short and open faults is evaluated under both normal and reverse bias (i.e., switch ground and VDD) conditions. In the FIG. 12A example, two layout analyses are performed. The first is a “normal” layout analysis based on normal supply/bias conditions and identifies the short/open faults (and corresponding structures) that can be observed under a normally biased VCI scan. The second layout analysis is an alternative layout analysis based on reversed supply/bias conditions that identifies the short/open faults (and corresponding structures) that can be observed under a reverse biased VCI scan. Next, a choose is made between a normal or reverse biased scan, based on defect coverage and/or scanning efficiency, and based on that choice, one or the other of those two scans is performed.

In the FIG. 12B embodiment, the first and second layout analyses are the same. But because both scans will be performed, the scan selection undertakes an additional step of deciding which features to scan in first (normal) scan and which to scan in the second (reverse biased) scan, so as to avoid redundancy and maximize scanning efficiency (as previously defined).

What we claim in this application is:

1. A method of testing a processed semiconductor wafer, using voltage contrast inspection (VCI), to detect manufacturing defects therein, said process comprising at least the following steps:
(a) performing a computer-assisted layout analysis of the wafer's design to identify features on the wafer where a short or open defect would be observable by VCI;
(b) based on available scanning capacity of a VCI scanner, selecting features corresponding to a subset of the observable short and/or open defects identified in step (a) for targeting by the VCI scanner;
(c) scanning only the selected features to determine the presence or absence of the observable defects selected in step (b);
(d) whereby a the VCI scanner targets and evaluates a majority of the total VCI-observable defects in a single pass.

2. A method as defined in claim 1, wherein the layout analysis of step (a) only considers open defects.

3. A method as defined in claim 2, wherein the layout analysis ignores redundant segments.

4. A method as defined in claim 2, wherein the layout analysis ignores features where a distance from a line end to a via is too short to permit defect detection by VCI.

5. A method as defined in claim 2, where the layout analysis ignores features that are not grounded.

6. A method as defined in claim 1, wherein the layout analysis of step (a) only considers short defects.

7. A method as defined in claim 6, wherein the layout analysis ignores hard grounded features.

8. A method as defined in claim 6, wherein the layout analysis ignores features that would be unobservable because of an absence of any brighter neighbor.

9. A method as defined in claim 1, further comprising the step of:
(a2) performing a second computer-assisted layout analysis of the wafer's design to identify features on the wafer where a short or open defect would be observable by VCI under reverse biased conditions.

10. A method, as defined in claim 9, wherein the layout analyses of steps (a) and (a2) are compared and used to determine whether to scan using normal or reverse bias conditions.

11. A method, as defined in claim 9, wherein the layout analyses of steps (a) and (a2) are analyzed to determine which defects to scan using normal bias conditions and which defects to scan using reverse bias conditions.
